(19) United States
(12) Patent Application Publication
(10) Pub. No.: US 2016/0178657 A9
(43) Pub. Date: Jun. 23, 2016

(54) SYSTEMS AND METHODS FOR SENSOR CALIBRATION

(71) Applicant: InvenSense, Incorporated, San Jose, CA (US)

(72) Inventors: Sinan Karahan, Menlo Park, CA (US); Shang-Hung Lin, San Jose, CA (US); Alexey Morozov, Sunnyvale, CA (US)

(73) Assignee: InvenSense, Incorporated, San Jose, CA (US)

(21) Appl. No.: 14/247,142

(22) Filed: Apr. 7, 2014

Related U.S. Application Data
(60) Provisional application No. 61/920,265, filed on Dec. 23, 2013.

(51) Int. Cl. G01P 21/00; G01R 35/00; G01C 25/00

(52) U.S. Cl. CPC G01P 21/00; G01C 25/005; G01R 35/005

(57) ABSTRACT

Systems and methods are disclosed for calibrating a sensor. A recursive least squares estimation may be performed to update a mean and a covariance matrix for samples of data from a motion sensor and a bias estimate for the motion sensor may be derived from the mean and covariance matrix. The motion sensor may be an gyroscope, an accelerometer or a magnetometer.

### FIELD OF THE PRESENT DISCLOSURE

This disclosure generally relates to the calibration of sensors and more specifically to initiating the calibration of a motion sensor in an efficient manner.

### BACKGROUND

The development of microelectromechanical systems (MEMS) has enabled the incorporation of a wide variety of sensors into mobile devices, such as cell phones, laptops, tablets, gaming devices and other portable, electronic devices. Non-limiting examples of such sensors include an accelerometer, a gyroscope, a magnetometer, a pressure sensor, a microphone, a proximity sensor, an ambient light sensor, an infrared sensor, and the like. Further, sensor fusion processing may be performed to combine the data from a plurality of sensors to provide an improved characterization of the device's motion or orientation. However, due to the nature of electronics and mechanics, MEMS-based sensors may be prone to having bias (offset) and sensitivity errors. These errors may drift and or change due to temperature, humidity, time, assembly stress and other changes in peripheral conditions. In turn, inaccurate bias may result in decreased quality of sensor data and may complicate the sensor fusion process used to estimate parameters such as attitude (e.g., pitch, roll, and yaw), heading reference and the like which are dependent on the precision of the sensors' outputs. For example, when integration of raw data output by the sensor is used to determine velocity from acceleration or orientation angle from the rate of angular change, the bias drift problem may be significantly magnified.

In light of these characteristics of MEMS sensors, it may be desirable to perform a sensor calibration operation to characterize the bias or sensitivity error, enabling a correction of the sensor data. A sensor calibration operation may employ mathematical calculations to deduce various motion states and the position or orientation of a physical system. A sensor bias may be produced by the calibration operation, which may then be applied to the raw sensor data and calibrate the sensor. As will be appreciated, the calibration operation may be performed during manufacture or may be performed periodically while the device is being used to account for changes that may occur over time.

Particularly for mobile devices that may rely on a battery for energy or may have limited computational abilities, the use of sensor fusion involving multiple sensor systems may represent an undesirably large portion of the resource budget. Accordingly, the techniques of this disclosure are directed to efficiently calibrating a motion sensor in order to minimize power consumption or reduce computational overhead. While the following discussion is in the context of MEMS sensors as used in portable devices, one of skill in the art will recognize that these techniques may be employed to any suitable sensor application as desired.

### SUMMARY

As will be described in detail below, this disclosure includes a method for calibrating a motion sensor including obtaining a plurality of data samples from the motion sensor, performing a recursive least squares estimation to update a mean and a covariance matrix for each of the plurality of data samples and deriving a bias estimate for the motion sensor from the mean and covariance matrix.

In one aspect, the motion sensor may be a gyroscope. Further, each of the plurality of data samples may be a measured angular rate so that the method includes obtaining a corrected attitude for each sample from sensor fusion data, determining an angular rate corresponding to the corrected attitude and performing the recursive least squares estimation using each measured angular rate and each determined angular rate to derive the bias.

In another aspect, the motion sensor may be an accelerometer. As such, a standard deviation may be determined using the plurality of data samples and the least square estimation may be performed for a first data sample depending on a comparison to the standard deviation. Further, a covariance value and an innovation value may be determined with respect to the first data sample and the bias derived using the first data sample depending on a comparison to the covariance value and the innovation value.

In one embodiment, each of the plurality of data samples may be rotated to a world coordinate frame, a gravity vector for each of the rotated plurality of data samples may be determined, the determined gravity vectors as adjusted by a bias may be set equal and the recursive least squares estimation may be performed to solve for the bias.

In another embodiment, the plurality of data samples may be fit to a sphere having a radius equal to a gravitational constant and the recursive least squares estimation may be performed to determine a center of the sphere by computing Cartesian coordinates of the plurality of data samples, wherein the center corresponds to the bias. Further, computing Cartesian coordinates of the plurality of data samples may include grouping non-linear terms as an unknown in the recursive least squares estimation.

In another embodiment, the plurality of data samples may be fit to a sphere having a radius equal to a gravitational constant, a first vector may be generated from a pair of data samples of the plurality of data samples, a second vector may be generated from another pair of data samples of the plurality of data samples and the recursive least squares estimation may be performed to determine a center of the sphere by computing an intersection of perpendiculars of the first vector and the second vector, wherein the center corresponds to the bias.

In yet another embodiment, the plurality of data samples may be fit to a sphere having a radius equal to a gravitational constant and the recursive least squares estimation may be performed to determine a center of the sphere by subtracting a first data sample of the plurality of data samples taken at a first time from a second data sample of the plurality of data samples taken at a second time, wherein the center corresponds to the bias.

Other aspects relate to the use of a magnetometer as the motion sensor. As desired, an innovation vector corresponding to the recursive least squares estimation may be determined and a magnetic anomaly detected based at least in part on the innovation vector.

In one embodiment, a standard deviation using the plurality of data samples may be determined, an absolute value of the difference between a first data sample and the derived bias may be determined and the recursive least square estimate may be performed with respect to the first data sample depending on a comparison to the standard deviation and the absolute value. Further, an absolute value of a difference between a reference radius and a distance with respect to the derived bias and the first data sample may be determined, a maximum diagonal covariance value with respect to the first sample may be determined and the bias may be derived using the first data sample depending on a comparison to the absolute value and the maximum diagonal covariance value.

In one embodiment, each of the plurality of data samples may be rotated to a world coordinate frame, a reference vector corresponding to the Earth's magnetic field for each of the rotated plurality of data samples may be determined, the determined gravity vectors may be set equal and the recursive least squares estimation may be performed to derive the bias.

In another embodiment, the plurality of data samples may be fit to a sphere having a radius equal to a magnitude of the Earth's magnetic field and the recursive least squares estimation may be performed to determine a center of the sphere by computing Cartesian coordinates of the plurality of data samples, wherein the center corresponds to the bias. Further, computing Cartesian coordinates of the plurality of data samples may include grouping non-linear terms as an unknown in the recursive least squares estimation.

In another embodiment, the plurality of data samples may be fit to a sphere having a radius equal to a magnitude of the Earth's magnetic field; a first vector may be generated from a pair of data samples of the plurality of data samples, a second vector may be generated from another pair of data samples of the plurality of data samples and the recursive least squares estimation may be performed to determine a center of the sphere by computing an intersection of perpendiculars of the first vector and the second vector, wherein the center corresponds to the bias.

In yet another embodiment, the plurality of data samples may be fit to a sphere having a radius equal to a magnitude of the Earth's magnetic field and the recursive least squares estimation may be performed to determine a center of the sphere by subtracting a first data sample of the plurality of data samples taken at a first time from a second data sample of the plurality of data samples taken at a second time, wherein the center corresponds to the bias.

In one embodiment, the sensor may be calibrated on a single axis.

In one embodiment, a temperature of the motion sensor may be sensed and a temperature compensation may be provided to the calibration based at least in part on the sensed temperature. Further, the temperature compensation may be determined using a recursive least squares estimation.

In one embodiment, a confidence metric may be determined based at least in part on the covariance matrix.

This disclosure also includes a sensor device having at least one motion sensor outputting a plurality of data samples and a calibration module configured to perform a recursive least squares estimation to update a mean and a covariance matrix for each of the plurality of data samples and derive a bias estimate for the motion sensor from the mean and covariance matrix.

In one embodiment, the motion sensor is a gyroscope. Further, each of the plurality of data samples may be a measured angular rate so that the calibration module may obtain a corrected attitude for each sample from sensor fusion data, determine an angular rate corresponding to the corrected attitude and perform the recursive least squares estimation using each measured angular rate and each determined angular rate to derive the bias.

In another aspect, the motion sensor may be an accelerometer. As such, the calibration module may determine a standard deviation using the plurality of data samples and perform the least square estimation for a first data sample depending on a comparison to the standard deviation. Further, the calibration module may determine a covariance value and an innovation value with respect to the first data sample and derive the bias using the first data sample depending on a comparison to the covariance value and the innovation value.

In one embodiment, the calibration module may rotate each of the plurality of data samples to a world coordinate frame, determine a gravity vector for each of the rotated plurality of data samples, set the determined gravity vectors equal and perform the recursive least squares estimation to derive the bias.

In another embodiment, the calibration module may fit the plurality of data samples to a sphere having a radius equal to a gravitational constant and perform the recursive least squares estimation to determine a center of the sphere by computing Cartesian coordinates of the plurality of data samples, wherein the center corresponds to the bias. Further, computing Cartesian coordinates of the plurality of data samples may include grouping non-linear terms as an unknown in the recursive least squares estimation.

In another embodiment, the calibration module may fit the plurality of data samples to a sphere having a radius equal to a gravitational constant, generate a first vector from a pair of data samples of the plurality of data samples, generate a second vector from another pair of data samples of the plurality of data samples and perform the recursive least squares estimation to determine a center of the sphere by computing an intersection of perpendiculars of the first vector and the second vector, wherein the center corresponds to the bias.

In yet another embodiment, the calibration module may fit the plurality of data samples to a sphere having a radius equal to a gravitational constant and perform the recursive least squares estimation to determine a center of the sphere by subtracting a first data sample of the plurality of data samples taken at a first time from a second data sample of the plurality of data samples taken at a second time, wherein the center corresponds to the bias.

In one embodiment, the motion sensor may be a magnetometer. As desired, the calibration module may determine an innovation vector corresponding to the recursive least squares estimation and detect a magnetic anomaly based at least in part on the innovation vector.

In one embodiment, the calibration module may determine a standard deviation using the plurality of data samples, determine an absolute value of the difference between a first data sample and the derived bias and perform the recursive least square estimate with respect to the first data sample depending on a comparison to the standard deviation and the absolute value. Further, the calibration module may determine an absolute value of a difference between a reference radius and a distance with respect to the derived bias and the first data sample, determine a maximum diagonal covariance value with respect to the first sample and derive the bias using the first data sample depending on a comparison to the absolute value and the maximum diagonal covariance value.

In one embodiment, the calibration module may rotate each of the plurality of data samples to a world coordinate frame, determine a reference vector corresponding to the Earth's magnetic field for each of the rotated plurality of data samples, set the determined gravity vectors equal and perform the recursive least squares estimation to derive the bias.

In another embodiment, the calibration module may fit the plurality of data samples to a sphere having a radius equal to a magnitude of the Earth's magnetic field and perform the recursive least squares estimation to determine a center of the sphere by computing Cartesian coordinates of the plurality of data samples, wherein the center corresponds to the bias. Further, computing Cartesian coordinates of the plurality of data samples may include grouping non-linear terms as an unknown in the recursive least squares estimation.

In another embodiment, the calibration module may fit the plurality of data samples to a sphere having a radius equal to a magnitude of the Earth's magnetic field, generate a first vector from a pair of data samples of the plurality of data samples, generate a second vector from another pair of data samples of the plurality of data samples and perform the recursive least squares estimation to determine a center of the sphere by computing an intersection of perpendiculars of the first vector and the second vector, wherein the center corresponds to the bias.

In yet another embodiment, the calibration module may fit the plurality of data samples to a sphere having a radius equal to a magnitude of the Earth's magnetic field and perform the recursive least squares estimation to determine a center of the sphere by subtracting a first data sample of the plurality of data samples taken at a first time from a second data sample of the plurality of data samples taken at a second time, wherein the center corresponds to the bias.

In one embodiment, the calibration module may be configured to calibrate the sensor on a single axis.

In one embodiment, the sensor device may include a temperature sensor and the calibration module may be configured to provide a temperature compensation to the calibration based at least in part on a sensed temperature. Further, the calibration module may be configured to determine the temperature compensation using a recursive least squares estimation.

In one embodiment, the calibration module may be configured to determine a confidence metric based at least in part on the covariance matrix.

This disclosure is also directed to a self-calibrating sensor device having at least one motion sensor outputting a plurality of data samples and a calibration module that may derive a bias estimate for the motion sensor, wherein the at least one motion sensor and the calibration module are implemented on a single substrate

### BRIEF DESCRIPTION OF THE DRAWINGS

FIG. 1 is a schematic diagram of device configured to calibrate a motion sensor using a recursive least squares estimation to derive a bias according to an embodiment.

FIG. 2 is a flow chart showing a recursive least squares estimation of the error between the calculated sensor fusion attitude and the measured angular rate according to an embodiment.

FIG. 3 is a schematic diagram of the orientation of a device with respect to gravity according to an embodiment.

FIG. 4 is schematic diagram showing the fitting of accelerometer data to a sphere according to an embodiment.

FIG. 5 is schematic diagram representing a state machine for determining whether to process accelerometer data in a recursive least squares estimation according to an embodiment.

FIG. 6 is schematic diagram representing a state machine for determining whether to apply a bias derived from a recursive least squares estimation to an accelerometer according to an embodiment.

FIG. 7 is schematic diagram representing a state machine for determining whether to process magnetometer data in a recursive least squares estimation according to an embodiment.

FIG. 8 is schematic diagram representing a state machine for determining whether to apply a bias derived from a recursive least squares estimation to a magnetometer according to an embodiment.

### DETAILED DESCRIPTION

At the outset, it is to be understood that this disclosure is not limited to particularly exemplified materials, architectures, routines, methods or structures as such may vary. Thus, although a number of such options, similar or equivalent to those described herein, can be used in the practice or embodiments of this disclosure, the preferred materials and methods are described herein.

It is also to be understood that the terminology used herein is for the purpose of describing particular embodiments of this disclosure only and is not intended to be limiting.

The detailed description set forth below in connection with the appended drawings is intended as a description of exemplary embodiments of the present disclosure and is not intended to represent the only exemplary embodiments in which the present disclosure can be practiced. The term “exemplary” used throughout this description means “serving as an example, instance, or illustration,” and should not necessarily be construed as preferred or advantageous over other exemplary embodiments. The detailed description includes specific details for the purpose of providing a thorough understanding of the exemplary embodiments of the specification. It will be apparent to those skilled in the art that the exemplary embodiments of the specification may be practiced without these specific details. In some instances, well known structures and devices are shown in block diagram form in order to avoid obscuring the novelty of the exemplary embodiments presented herein.

For purposes of convenience and clarity only, directional terms, such as top, bottom, left, right, up, down, over, above, below, beneath, rear, back, and front, may be used with respect to the accompanying drawings or chip embodiments. These and similar directional terms should not be construed to limit the scope of the disclosure in any manner.

In this specification and in the claims, it will be understood that when an element is referred to as being “connected to” or “coupled to” another element, it can be directly connected or coupled to the other element or intervening elements may be present. In contrast, when an element is referred to as being “directly connected to” or “directly coupled to” another element, there are no intervening elements present.

Some portions of the detailed descriptions which follow are presented in terms of procedures, logic blocks, processing and other symbolic representations of operations on data bits within a computer memory. These descriptions and representations are the means used by those skilled in the data processing arts to most effectively convey the substance of their work to others skilled in the art. In the present application, a procedure, logic block, process, or the like, is conceived to be a self-consistent sequence of steps or instructions leading to a desired result. The steps are those requiring physical manipulations of physical quantities. Usually, although not necessarily, these quantities take the form of electrical or magnetic signals capable of being stored, transferred, combined, compared, and otherwise manipulated in a computer system.

It should be borne in mind, however, that all of these and similar terms are to be associated with the appropriate physical quantities and are merely convenient labels applied to these quantities. Unless specifically stated otherwise as apparent from the following discussions, it is appreciated that throughout the present application, discussions utilizing the terms such as “accessing,” “receiving,” “sending,” “using,” “selecting,” “determining,” “normalizing,” “multiplying,” “averaging,” “monitoring,” “comparing,” “applying,” “updating,” “measuring,” “deriving” or the like, refer to the actions and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Embodiments described herein may be discussed in the general context of processor-executable instructions residing on some form of non-transitory processor-readable medium, such as program modules, executed by one or more computers or other devices. Generally, program modules include routines, programs, objects, components, data structures, etc., that perform particular tasks or implement particular abstract data types. The functionality of the program modules may be combined or distributed as desired in various embodiments.

In the figures, a single block may be described as performing a function or functions; however, in actual practice, the function or functions performed by that block may be performed in a single component or across multiple components, and/or may be performed using hardware, using software, or using a combination of hardware and software. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure. Also, the exemplary wireless communications devices may include components other than those shown, including well-known components such as a processor, memory and the like.

The techniques described herein may be implemented in hardware, software, firmware, or any combination thereof, unless specifically described as being implemented in a specific manner. Any features described as modules or components may also be implemented together in an integrated logic device or separately as discrete but interoperable logic devices. If implemented in software, the techniques may be realized at least in part by a non-transitory processor-readable storage medium comprising instructions that, when executed, performs one or more of the methods described above. The non-transitory processor-readable data storage medium may form part of a computer program product, which may include packaging materials.

The non-transitory processor-readable storage medium may comprise random access memory (RAM) such as synchronous dynamic random access memory (SDRAM), read only memory (ROM), non-volatile random access memory (NVRAM), electrically erasable programmable read-only memory (EEPROM), FLASH memory, other known storage media, and the like. The techniques additionally, or alternatively, may be realized at least in part by a processor-readable communication medium that carries or communicates code in the form of instructions or data structures and that can be accessed, read, and/or executed by a computer or other processor. For example, a carrier wave may be employed to carry computer-readable electronic data such as those used in transmitting and receiving electronic mail or in accessing a network such as the Internet or a local area network (LAN). Of course, many modifications may be made to this configuration without departing from the scope or spirit of the claimed subject matter.

The various illustrative logical blocks, modules, circuits and instructions described in connection with the embodiments disclosed herein may be executed by one or more processors, such as one or more motion processing units (MPUs), digital signal processors (DSPs), general purpose microprocessors, application specific integrated circuits (ASICs), application specific instruction set processors (ASIPs), field programmable gate arrays (FPGAs), or other equivalent integrated or discrete logic circuitry. The term “processor,” as used herein may refer to any of the foregoing structure or any other structure suitable for implementation of the techniques described herein. In addition, in some aspects, the functionality described herein may be provided within dedicated software modules or hardware modules configured as described herein. Also, the techniques could be fully implemented in one or more circuits or logic elements. A general purpose processor may be a microprocessor, but in the alternative, the processor may be any conventional processor, controller, microcontroller, or state machine. A processor may also be implemented as a combination of computing devices, e.g., a combination of an MPU and a microprocessor, a plurality of microprocessors, one or more microprocessors in conjunction with an MPU core, or any other such configuration.

Unless defined otherwise, all technical and scientific terms used herein have the same meaning as commonly understood by one having ordinary skill in the art to which the disclosure pertains.

Finally, as used in this specification and the appended claims, the singular forms “a, “an” and “the” include plural referents unless the content clearly dictates otherwise.

In the described embodiments, a chip is defined to include at least one substrate typically formed from a semiconductor material. A single chip may be formed from multiple substrates, where the substrates are mechanically bonded to preserve the functionality. A multiple chip includes at least two substrates, wherein the two substrates are electrically connected, but do not require mechanical bonding. A package provides electrical connection between the bond pads on the chip to a metal lead that can be soldered to a PCB. A package typically comprises a substrate and a cover. Integrated Circuit (IC) substrate may refer to a silicon substrate with electrical circuits, typically CMOS circuits. MEMS cap provides mechanical support for the MEMS structure. The MEMS structural layer is attached to the MEMS cap. The MEMS cap is also referred to as handle substrate or handle wafer. In the described embodiments, an electronic device incorporating a sensor may employ a motion tracking module also referred to as Motion Processing Unit (MPU) that includes at least one sensor in addition to electronic circuits. The sensor, such as a gyroscope, a compass, a magnetometer, an accelerometer, a microphone, a pressure sensor, a proximity sensor, or an ambient light sensor, among others known in the art, are contemplated. Some embodiments include accelerometer, gyroscope, and magnetometer, which each provide a measurement along three axes that are orthogonal relative to each other referred to as a 9-axis device. Other embodiments may not include all the sensors or may provide measurements along one or more axes. The sensors may be formed on a first substrate. Other embodiments may include solid-state sensors or any other type of sensors. The electronic circuits in the MPU receive measurement outputs from the one or more sensors. In some embodiments, the electronic circuits process the sensor data. The electronic circuits may be implemented on a second silicon substrate. In some embodiments, the first substrate may be vertically stacked, attached and electrically connected to the second substrate in a single semiconductor chip, while in other embodiments, the first substrate may be disposed laterally and electrically connected to the second substrate in a single semiconductor package.

In one embodiment, the first substrate is attached to the second substrate through wafer bonding, as described in commonly owned U.S. Pat. No. 7,104,129, which is incorporated herein by reference in its entirety, to simultaneously provide electrical connections and hermetically seal the MEMS devices. This fabrication technique advantageously enables technology that allows for the design and manufacture of high performance, multi-axis, inertial sensors in a very small and economical package. Integration at the wafer-level minimizes parasitic capacitances, allowing for improved signal-to-noise relative to a discrete solution. Such integration at the wafer-level also enables the incorporation of a rich feature set which minimizes the need for external amplification.

In the described embodiments, raw data refers to measurement outputs from the sensors which are not yet processed. Motion data refers to processed raw data. In many situations, operations known as sensor fusion may involve combining data obtained from multiple sensors to improve accuracy and usefulness of the sensor data, such as by refining orientation information or characterizing a bias that may be present in a given sensor. Thus, processing may include applying a sensor fusion algorithm or applying any other algorithm to provide enhanced data. In the described embodiments, a MPU may include processors, memory, control logic and sensors among structures.

As noted above, certain techniques of this disclosure are directed to the calibration of motion sensors including gyroscopes, accelerometers, and magnetometers, during the manufacturing phase as well as at the end-user. The disclosed on-sensor calibration requires no computation from host processor. The invention takes advantage of integrated sensors by using one sensor, for example gyroscopes, as reference to calibrate another sensor, for example accelerometers.

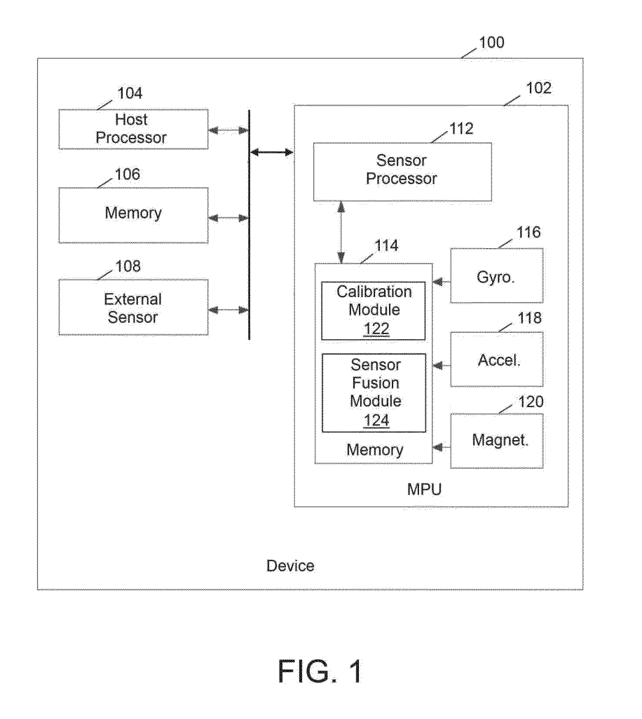

Details regarding one embodiment of a mobile electronic device 100 including features of this disclosure are depicted as high level schematic blocks in FIG. 1. As will be appreciated, device 100 may be implemented as a device or apparatus, such as a handheld device that can be moved in space by a user and its motion and/or orientation in space therefore sensed. For example, such a handheld device may be a mobile phone (e.g., cellular phone, a phone running on a local network, or any other telephone handset), wired telephone (e.g., a phone attached by a wire), personal digital assistant (PDA), video game player, video game controller, navigation device, mobile internet device (MID), personal navigation device (PND), digital still camera, digital video camera, binoculars, telephoto lens, portable music, video, or media player, remote control, or other handheld device, or a combination of one or more of these devices.

In some embodiments, device 100 may be a self-contained device that includes its own display and other output devices in addition to input devices as described below. However, in other embodiments, device 100 may function in conjunction with another portable device or a non-portable device such as a desktop computer, electronic tabletop device, server computer, etc. which can communicate with the device 100, e.g., via network connections. The device may be capable of communicating via a wired connection using any type of wire-based communication protocol (e.g., serial transmissions, parallel transmissions, packet-based data communications), wireless connection (e.g., electromagnetic radiation, infrared radiation or other wireless technology), or a combination of one or more wired connections and one or more wireless connections.

As shown, device 100 includes MPU 102, host processor 104, host memory 106, and may include one or more sensors, such as external sensor 108. Host processor 104 may be configured to perform the various computations and operations involved with the general function of device 100. Host processor 104 may be coupled to MPU 102 through bus 110, which may be any suitable bus or interface, such as a peripheral component interconnect express (PCIe) bus, a universal serial bus (USB), a universal asynchronous receiver/transmitter (UART) serial bus, a suitable advanced microcontroller bus architecture (AMBA) interface, an Inter-Integrated Circuit (I2C) bus, a serial digital input output (SDIO) bus, or other equivalent. Host memory 106 may include programs, drivers or other data that utilize information provided by MPU 102. Exemplary details regarding suitable configurations of host processor 104 and MPU 102 may be found in co-pending, commonly owned U.S. patent application Ser. No. 12/106,921, filed Apr. 21, 2008, which is hereby incorporated by reference in its entirety.

In this embodiment, MPU 102 is shown to include sensor processor 112, memory 114 and internal sensors, represented in the embodiment by gyroscope 116, accelerometer 118 and magnetometer 120. The internal sensors may be implemented as a MEMS-based motion sensor, including inertial sensors such as a gyroscope or accelerometer, or an electromagnetic sensor such as a Hall effect or Lorentz field magnetometer. As desired, one or more of the internal sensors may be configured to provide raw data output measured along three orthogonal axes or any equivalent structure. Memory 114 may store algorithms, routines or other instructions for processing data output by one or more internal sensors, including calibration module 122 as described in more detail below and sensor fusion module 124. If provided, external sensor 108 and/or an additional internal sensor may include one or more sensors, such as accelerometers, gyroscopes, magnetometers, pressure sensors, microphones, proximity, and ambient light sensors, and temperature sensors among others sensors. As used herein, an internal sensor refers to a sensor implemented using the MEMS techniques described above for integration with MPU 102 into a single chip. Similarly, an external sensor as used herein refers to a sensor carried on-board device 100 that is not integrated into MPU 102.

Even though embodiments are described in the context of internal sensors implemented in MPU 102, these techniques may be applied to a non-integrated sensor, such as external sensor 108 and likewise the calibration module may be implemented using instructions stored in any available memory resource, such as host memory 106, that may be executed using any available processor, such as host processor 104. Still further, the functionality performed by the calibration module may be implemented using any combination of hardware, firmware and software.

As will be appreciated, host processor 104 and/or sensor processor 112 may be one or more microprocessors, central processing units (CPUs), or other processors which run software programs for device 100 or for other applications related to the functionality of device 100. For example, different software application programs such as menu navigation software, games, camera function control, navigation software, and phone or a wide variety of other software and functional interfaces can be provided. In some embodiments, multiple different applications can be provided on a single device 100, and in some of those embodiments, multiple applications can run simultaneously on the device 100. Multiple layers of software can be provided on a computer readable medium such as electronic memory or other storage medium such as hard disk, optical disk, flash drive, etc., for use with host processor 104 and sensor processor 112. For example, an operating system layer can be provided for device 100 to control and manage system resources in real time, enable functions of application software and other layers, and interface application programs with other software and functions of device 100. In some embodiments, one or more motion algorithm layer may provide motion algorithms for lower-level processing of raw sensor data provided from internal or external sensors. Further, a sensor device driver layer may provide a software interface to the hardware sensors of device 100. Some or all of these layers can be provided in host memory 106 for access by host processor 104, in memory 114 for access by sensor processor 112, or in any other suitable architecture.

In some embodiments, it will be recognized that the exemplary architecture depicted in FIG. 1 may allow the calibration of one or more internal sensors to be performed using MPU 102 and may not require involvement of host processor 104 and/or host memory 106. Such an embodiment may be termed a self-calibrating MPU and, as described above, may be implemented with internal sensor or sensors 116 on a single substrate. Moreover, as will be described below, the calibration techniques may be implemented using computationally efficient algorithms to reduce processing overhead and power consumption.

Notably, techniques of this disclosure are adapted to processing data samples by generating and updating a mean and a covariance matrix for each sample and performing a recursive least squares estimation to determine a bias in the motion sensor. In some embodiments, this may involve using data from one internal sensor as a reference to perform a calibration routine with respect to another internal sensor. Thus, the solutions obtained using recursive least squares estimation may be used to calibrate a motion sensor in a computationally and power efficient manner.

Accordingly, in one aspect of this disclosure, suitable techniques of applying a recursive least squares estimation may be expressed in relation to a single linear algebraic equation representing data from a motion sensor at a sample time t written as Equation 1, in which aⱼ(t)(j=1, 2, . . . , n) and c(t) are known measurement data and xⱼ (j=1, 2, . . . , n) are parameters to be determined.

a₁(t)x₁+a₂(t)x₂+ . . . aₙ(t)xₙ=c(t) (1)

Equation 1 may be evaluated over time at samples t₁, t₂, . . . , tₘ, in which m can be less than, equal to, or greater than n, the number of parameters to be determined. By setting matrix A wherein aᵢⱼ=aᵢ(tⱼ), (i=1, 2, . . . , n; j=1, 2, . . . , m), matrix x wherein xⱼ(j=1, 2, . . . , n) and matrix c wherein cᵢ(i=1, 2, . . . , m), the resulting set of linear algebraic equations may be expressed in matrix-vector terms as Equation 2.

Ax=c (2)

As will be recognized, when matrix A is of full rank, and m is equal to, or greater than n, a least square technique for solving for matrix x may be represented by Equation 3.

x=(A^{T}A)⁻¹A^{T}c (3)

Correspondingly, solving Equation 3 may involve updating the n×n matrix A^{T} A and performing a matrix inversion operation at each sample tⱼ. As will be appreciated, the complexity associated with matrix inversion increases rapidly with the size of the matrix and may require significant computational resources. Further, samples in which matrix A^{T} A is singular may prevent performing the matrix inversion.

To avoid these limitations, the techniques of this disclosure apply a recursive least squares estimation that may be expressed as Equation 4, in which the mean k given by Equation 5 and the n×n covariance matrix Pⱼ given by Equation 6 are subjected to a forgetting factor α in the range of 0<α≦1 and updated at each sample.

$$\begin{matrix}{x}_{j + 1} = {x}_{j} + k ( {c}_{j} - {a}_{j}^{T} {x}_{j} ) & ( 4 ) \\ k = \frac{1}{α + {a}_{j}^{T } {P}_{j} {a}_{j}} {P}_{j} {a}_{j} & ( 5 ) \\ {P}_{j} = \frac{1}{α} [ 1 - {ka}_{j}^{T} ] {P}_{j } {a}_{j} & ( 6 )\end{matrix}$$

In some embodiments, the recursive least squares estimation represented by Equations 4-6 may be initiated by setting P₀ to a large diagonal matrix and by setting x₀ to an initial estimation, such as from a previously performed calibration or any other suitable source. Since the recursive least squares estimation techniques used in this disclosure employ scalar division as compared to the matrix inversion associated with the least square technique represented by Equation 3, significant computational efficiencies may be achieved. Further, Equations 4-6 do not require a matrix-vector form, thus avoiding the requirement that matrix A be non-singular as discussed above. It will be recognized that the above equations represent one suitable formulation of a recursive least squares estimation algorithm, but other equations and formulations may be employed as desired.

Conventional gyroscope calibration methods typically involve computing the bias offsets along each sensor axis under stationary conditions. These bias values may then be subtracted from the gyroscope measurement during a sensor fusion operation. However, methods that require the gyroscope to remain stationary may not maintain accurate bias determinations when the gyroscope is in motion for extended periods. Further, the conventional techniques may not be used to compute other sensor mis-calibrations that require different conditions. For example, determining the scale error (sensitivity) of the gyroscope measurements along each axis may require that the sensor be in motion.

Accordingly, calibration module 122 may be configured to implement a recursive least squares estimation to calibrate gyroscope 116 in one embodiment. A plurality of data samples may be output by gyroscope 116 corresponding to rates of angular change along the orthogonal axes measured by the gyroscope. Further, calibration module 122 may obtain a corrected attitude for each sample from sensor fusion module 124. After determining an angular rate corresponding to the corrected attitude, calibration module 122 may perform a recursive least squares estimation using the measured angular rate and the determined angular rate for each sample to determine a bias for gyroscope 116.

For example, for a measured angular rate of ωₘ and a true angular rate of ω_{T}, a linear model of the gyroscope measurement correction may be expressed as Equation 7, in which the correction matrix S=S₁+S₂ is symmetric, the gyroscope sensitivity or scale error coefficient array is S_{scals}=[sₓₓ s_{yy} s_{zz}]′, S₁=diag([sₓₓ s_{yy} s_{zz}]′), the gyroscope skew error coefficients representing non-orthogonality of the sensor principal axes is S_{skew}=[s_{xy} s_{xz} s_{yz}]′ and b is the gyroscope bias matrix b=[bₓ b_{y} b_{z}]′.

$${ω}_{T} [ \begin{matrix}1 + {s}_{xx} & {s}_{xy} & {s}_{xz} \\ {s}_{xy} & 1 + {s}_{yy} & {s}_{yz} \\ {s}_{xz} & {s}_{yz} & 1 + {s}_{zz}\end{matrix} ] {ω}_{m} - b = ( I + {S}_{1} + {S}_{2} ) {ω}_{m} - b \qquad ( 7 )$$

When a plurality of samples are used to provide the measured and true angular rates, ωₘ and ω_{T}, the unknown coefficients b, S_{scale} and S_{skew} may be estimated using a recursive least squares estimation. In order to facilitate these calculations, Equation 7 may be reorganized as Equation 8, such that Δω=ω_{T}−ωₘ.

$$[ [ \begin{matrix}- 1 & 0 & 0 \\ 0 & - 1 & 0 \\ 0 & 0 & - 1\end{matrix} ] [ \begin{matrix}{ω}_{mx} & 0 & 0 \\ 0 & {ω}_{my} & 0 \\ 0 & 0 & {ω}_{mz}\end{matrix} ] [ \begin{matrix}{ω}_{my} & {ω}_{mz} & 0 \\ {ω}_{mx} & 0 & {ω}_{mz} \\ 0 & {ω}_{mx} & {ω}_{my}\end{matrix} ] ] [ \begin{matrix}b \\ {S}_{scale} \\ {S}_{skew}\end{matrix} ] = Δ ω \qquad ( 8 )$$

As will be appreciated, Equation 8 has the same form as Equation 2, allowing for application of the recursive least squares estimation Equations 4-6 to compute the mean and covariance matrix where the matrix A and the matrix c may be built from multiple measurements of ωₘ and ω_{T}. Accordingly, the bias and scale estimation may be expressed as recursive least squares estimation problems driven by the “measurements” ωₘ and “measurement errors” ∫ₚ, with unknowns being solved by minimizing the error in the solution of Equation 9.

$${min}_{χ} ‖ Ax - c ‖ \qquad ( 9 )$$

New measurements may be calculated at each step of sensor fusion and recursively added to the equations. As desired, the bias scale and skew terms may be computed in any combination by deleting the appropriate sub-matrices in Equation 8. In one embodiment, only the bias and scale (sensitivity) terms may be retained under the assumption that any skew misalignments may be sufficiently small to be ignored.

Under this implementation, values for ωₚ, and ω_{T} may be required to derive the solution. The ωₚ, term is output as the data from gyroscope 116, but ω_{T} may not be known directly. However, a suitable approximation for ω_{T} may be obtained by determining the angular rate that would correspond to the current attitude of device 100 which is available as an output from sensor fusion module 124.

For example, the attitude of device 100 may be expressed as the rotational operation that translates the body frame to the world frame. In some embodiments, rotation operation 200 may be expressed in the form of a unit quaternion. As used herein, the terms “quaternion” and “unit quaternion” may used interchangeably for convenience. Accordingly, a quaternion may be a four element vector describing the transition from one rotational orientation to another rotational orientation and may be used to represent the orientation of device 100. A unit quaternion has a scalar term and 3 imaginary terms. Thus, a rotation operation representing the attitude of device 100 may be described as a rotation of angle θ about the unit vector [uₓ, u_{y}, u_{z}] as indicated by Equation 10.

$$\overline{Q} = [ \begin{matrix}cos ( \frac{θ}{2} ) \\ sin ( \frac{θ}{2} ) \cdot {u}_{x} \\ sin ( \frac{θ}{2} ) \cdot {u}_{y} \\ sin ( \frac{θ}{2} ) \cdot {u}_{z}\end{matrix} ] \qquad ( 10 )$$

In other embodiments, rotation operation 200 may be expressed in any other suitable manner. For example, a rotation matrix employing Euler angles may be used to represent sequential rotations with respect to fixed orthogonal axes, such as rotations in the yaw, pitch and roll directions. As such, the operations described below may be modified as appropriate to utilize rotation matrices if desired.

Thus, sensor fusion module 124 may output an attitude at time t in the form of a quaternion q(t) representing the combination of sensor data from gyroscope 116 and accelerometer 118 or magnetometer 120 in the form of a 6-axis sensor fusion or the combination of gyroscope 116, accelerometer 118 and magnetometer 120 in the form of a 9-axis sensor fusion. For the techniques of this disclosure, the attitude output by sensor fusion module 124 may be taken as the correct attitude. In turn, Equation 11 expresses the relationship between the correct attitude q(t) and the true angular rate ω_{T}, where Ω(ω) is given by Equation 12.

$$\begin{matrix}\dot{q} ( t ) = \frac{q ( t + Δ t ) - q ( t )}{Δ t} = \frac{1}{2} Ω ( {ω}_{T} ) q ( t ) & ( 11 ) \\ Ω ( ω ) = [ \begin{matrix}0 & - {ω}_{x} & - {ω}_{y} & - {ω}_{z} \\ {ω}_{x} & 0 & {ω}_{z} & {ω}_{x} \\ {ω}_{y} & - {ω}_{z} & 0 & - {ω}_{y} \\ {ω}_{z} & {ω}_{y} & - {ω}_{x} & 0\end{matrix} ] & ( 12 )\end{matrix}$$

Additionally, a predicted attitude \tilde{q} generated from the measured angular rate ωₘ alone without sensor fusion correction from accelerometer 118 or magnetometer 120 may be expressed in terms of the same correct attitude as shown in Equation 13.

$$\dot{\tilde{q}} ( t ) = \frac{\tilde{q} ( t + Δ t ) - q ( t )}{Δ t} = \frac{1}{2} Ω ( {ω}_{m} ) q ( t ) \qquad ( 13 )$$

By subtracting Equation 13 from Equation 11, the difference between the true angular rate determined from an attitude obtained from sensor fusion module 124 and the measured angular rate obtained from the raw data output by gyroscope 116 is Δω as expressed by Equation 14 after simplifying and rearranging terms.

$$q ( t + Δ t ) - \tilde{q} ( t + Δ t ) = \frac{Δ t}{2} Ω ( {ω}_{T} - {ω}_{m} ) q ( t ) = \frac{Δ t}{2} Ω ( Δ ω ) q ( t ) \qquad ( 14 )$$

Equation 14 may be rewritten as Equation 15, wherein Q is defined as Equation 16.

$$\begin{matrix}q ( t + Δ t ) - \tilde{q} ( t + Δ t ) = \frac{Δ t}{2} Q ( q ( t ) ) [ \begin{matrix}0 \\ Δ {ω}_{x} \\ Δ {ω}_{y} \\ Δ {ω}_{z}\end{matrix} ] & ( 15 ) \\ Q ( q ) = [ \begin{matrix}{q}_{w} & - {q}_{x} & - {q}_{y} & - {q}_{z} \\ {q}_{x} & {q}_{w} & - {q}_{z} & {q}_{x} \\ {q}_{y} & {q}_{z} & {q}_{w} & - {q}_{y} \\ {q}_{z} & - {q}_{y} & {q}_{x} & {q}_{w}\end{matrix} ] & ( 16 )\end{matrix}$$

Given that the columns of Q(q) are orthonormal such that Q^{T}Q=I, the identity matrix, both sides of Equation 16 may be multiplied by Q^{T} to obtain Equation 17 using the orthonormality property.

$${Q}^{T} ( q ( t ) ) * ( q ( t + Δ t ) - \tilde{q} ( t + Δ t ) ) = \frac{Δ t}{2} [ \begin{matrix}0 \\ Δ {ω}_{x} \\ Δ {ω}_{y} \\ Δ {ω}_{z}\end{matrix} ] \qquad ( 17 )$$

Since the terms q(t), q(t+Δt), q(t+Δt) are available as discussed above, Δω may be computed as a recursive least squares estimation of the error between the attitude determined from sensor fusion module 124 and the measured angular rate obtained from gyroscope 116. This may be considered substantially equivalent to differentiating the attitude obtained from sensor fusion to calculate the true angular rate.

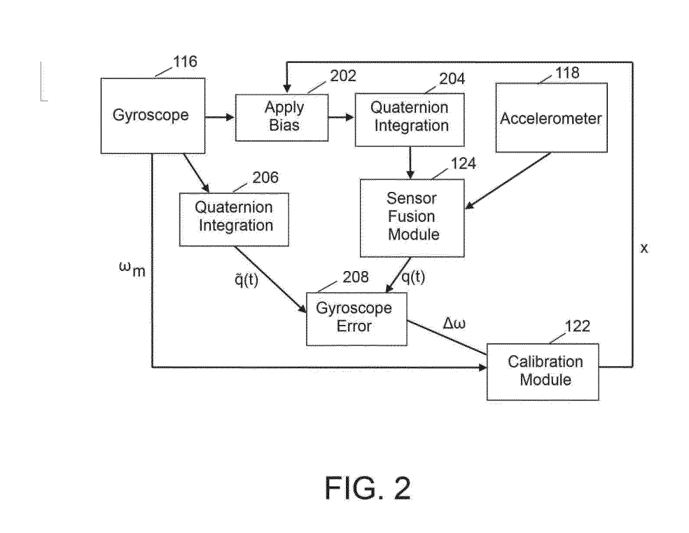

In one embodiment, the recursive least squares estimation techniques of this disclosure for calibrating gyroscope 116 may be represented by the schematic diagram depicted in FIG. 2 with a 6-axis sensor fusion operation combining data from gyroscope 116 and accelerometer 118. As shown, raw measured angular rate data from gyroscope 116 may be compensated in mixing block 202 by any bias determined from a previous calibration operation. The calibrated gyroscope data is then fed through a quaternion integration block 204 to generate a 3-axis gyroscope quaternion. The 3-axis gyroscope quaternion may in turn be fed to sensor fusion module 124 for combination with data from accelerometer 118, outputting a 6-axis quaternion that may be taken as a representation of the correct attitude of device 100 as described above. Similarly, the raw measured angular rate data from gyroscope 116 is also subjected to quaternion integration in block 206 to generate a 3-axis quaternion representing the measured angular rate data alone. The 6-axis quaternion and 3-axis quaternion may be used to determine a gyroscope error as represented by Δω using Equation 8 in block 208. The determined Δω along with the measured angular rate data ωₘ may be used by calibration module 122 in the recursive least squares estimation described above to determine bias and or sensitivity errors in gyroscope 116. As shown, these may be fed back to mixing block 202 to update the calibration and be applied to subsequent data samples from gyroscope 116.

In another aspect of this disclosure, calibration module 122 may be configured to perform a recursive least squares estimation to determine bias in accelerometer 118. As will be appreciated, accelerometer 116 outputs a combination of all the sensed accelerations (a combination of gravity, linear acceleration, centripetal acceleration, etc.) and the sensor bias. When in a motionless state, the output mainly consists of the gravity vector and bias. For an accelerometer output at time t given as a(t)=[aₓ(t) a_{y}(t) a_{z}(t)]^{T} and the bias x given as x=[bₓ b_{y} b_{z}]^{T} is the accelerometer bias, the gravity vector in world coordinate frame may be expressed in terms of as be represented as R_{b}^{w}(t₀), a 3×3 rotation matrix of the orientation of device 100 that converts body frame sensor data to world coordinate frame as indicated by Equation 18.

G_{w}=R_{b}^{w}(t_{g})·(a(t₀)⊕x) (18)

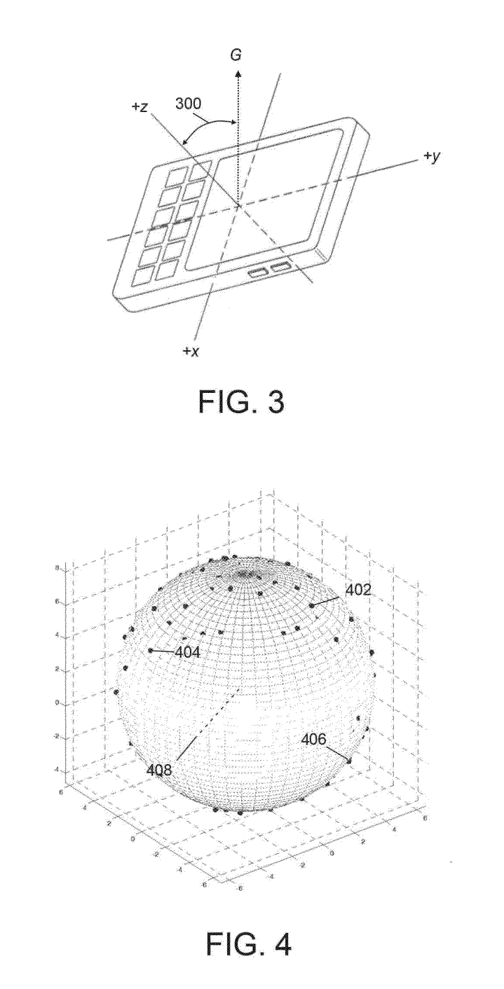

For example, the orientation of device 100 as depicted in FIG. 3 may be represented by rotation operation 300 that would align the Z axis of the body frame with the gravity vector.

When changing from a first motionless state to a second motionless state, the measured gravity vector translated to the world frame may be assumed to remain the same, as expressed by Equation 19 and further may be rearranged to result in Equation 20.

R_{b}^{w}(t₀)·(a(t₀)−x)=R_{b}^{w}(t₁)·a(t₁)−x) (19)

(R_{b}^{w}(t₁)−R_{b}^{w}(t₀))·x=R_{b}^{w}(t₁)·a(t₁)−R_{b}^{w}(t₀)·a(t₀) (20)

Since Equation 20 may be seen to have the same form as Equation 2 if A=R_{b}^{w}(t₁)−R_{b}^{w}(t₀) and c=R_{b}^{w}(t₁)·a(t₁)−R_{b}^{w}(t₀)·a(t₀), the recursive least squares estimation operations described above may be applied to derive a solution.

For example, for n+1 motionless states, A becomes a 3n×3 matrix as indicated by Equation 21 and c becomes a 3n×1 vector as indicated by Equation 22.

$$\begin{matrix}A {=}^{Δ} [ \begin{matrix}{R}_{b}^{w} ( {t}_{1} ) - {R}_{b}^{w} ( {t}_{0} ) \\ ⋮ \\ {R}_{b}^{w} ( {t}_{n} ) - {R}_{b}^{w} ( {t}_{n - 1} )\end{matrix} ] & ( 21 ) \\ c {=}^{Δ} [ \begin{matrix}{R}_{b}^{w} ( {t}_{1} ) \cdot a ( {t}_{1} ) - {R}_{b}^{w} ( {t}_{0} ) \cdot a ( {t}_{0} ) \\ ⋮ \\ {R}_{b}^{w} ( {t}_{n} ) \cdot a ( {t}_{n} ) - {R}_{b}^{w} ( {t}_{n - 1} ) \cdot a ( {t}_{n - 1} )\end{matrix} ] & ( 22 )\end{matrix}$$

Thus, by rotating the data samples from accelerometer 118 to the world coordinate frame and determining a gravity vector with respect to the rotated samples, the determined gravity vectors may be equated and a recursive least squares estimation may be performed to determine the bias by solving the unknown x=[bₓ b_{y} b_{z}]^{T} using Equations 4-6 as described above.

In another embodiment, data samples from accelerometer, such as 402-406, 118 may be fit to a sphere having a radius equal to a gravitational constant as shown in FIG. 4. Correspondingly, the recursive least squares estimation techniques of this disclosure may be applied to determine a center 408 of the sphere by computing Cartesian coordinates of the plurality of data samples, wherein the center corresponds to the bias of accelerometer 118.

For example, all accelerometer samples during a motionless state should reside on a sphere of radius r, corresponding to the gravitational constant. If [aₓ a_{y} a_{z}] represents an accelerometer sample at time t and the bias is represented by [bₓ b_{y} b_{z}], a sphere may be defined by Equation 23 which may be further expanded into Equation 24.

(aₓ−bₓ)²+(a_{y}−b_{y})²+(a_{z}−b_{z})²=r² (23)

aₓ¹−2aₓbₓ+bₓ²+a_{y}²−2a_{y}b_{y}+b_{y}²+a_{z}²−2a_{z}b_{z}+b_{z}²=r² (24)

Further, Equation 24 may be rewritten in matrix form, where c=r²−bₓ²−b_{y}²−b_{z}² as indicated by Equation 25 and simplified as Equation 26, where the unknown terms x=[bₓ b_{y} b_{z}, c].

$$\begin{matrix}[ \begin{matrix}2 {a}_{x} & 2 {a}_{y} & 2 {a}_{z} & 1\end{matrix} ] [ \begin{matrix}{b}_{x} \\ {b}_{y} \\ {b}_{z} \\ c\end{matrix} ] = {a}_{x}^{2} + {a}_{y}^{2} + {a}_{z}^{2} . & ( 25 ) \\ [ \begin{matrix}2 a & 1\end{matrix} ] X = {\vert a \vert}^{2} , & ( 26 )\end{matrix}$$

As will be appreciated, the non-linear terms represented by c have been grouped with the other unknown terms so that Equation 26 takes the form of Equation 2, allowing a recursive least squares estimation to be performed as discussed above with regards to Equations 4-6.

In yet another embodiment, data samples from accelerometer 118 again may be fit to a sphere having a radius equal to a gravitational constant, such as shown in FIG. 4. By generating vectors from pairs of data samples, the recursive least squares estimation techniques of this disclosure may be applied to determine the center of the sphere by computing an intersection of perpendiculars of the first vector and the second vector.

As before, if n+1 accelerometer outputs taken at time t (t₀, t₁, . . . , tₙ) are plotted in three dimensions, the data points will fall on the surface of a sphere with radius equal to the gravity magnitude g, and center at the bias x=[bₓ b_{y} b_{z}]^{T}. Vectors V₁ and V₂ may be generated as indicated by Equations 27 and 28, respectively.

$$\begin{matrix}{V}_{1} = a ( {t}_{1} ) - a ( {t}_{0} ) & ( 27 ) \\ {V}_{2} = \frac{a ( {t}_{1} ) + a ( {t}_{0} )}{2} - x & ( 28 )\end{matrix}$$

Since a(t₀) and a(t₁) may be assumed to lie on the surface of the sphere with a center x, the inner product of V₁ and V₂ will be zero as indicated by Equation 29.

V₁^{T}·V₂=0 (29)

In turn, substituting V₂ as given by Equation 28 allows Equation 29 to be rewritten as Equation 30 then rearranged to form Equation 31.

$$\begin{matrix}{V}_{1}^{T} \cdot ( \frac{a ( {t}_{1} ) + a ( {t}_{0} )}{2} - x ) = 0 & ( 30 ) \\ {V}_{1}^{T} \cdot x = {V}_{1}^{T} \cdot \frac{a ( {t}_{1} ) + a ( {t}_{0} )}{2} & ( 31 )\end{matrix}$$

Since Equation 31 may be seen to have the same form as Equation 2 if A=V₁^{T} and

$$c = {V}_{1}^{T} \cdot \frac{a ( {t}_{1} ) + a ( {t}_{0} )}{2} ,$$

the recursive least squares estimation operations described above may be applied to derive a solution for x, thereby deriving the bias for accelerometer 118.

In a further embodiment, data samples from accelerometer 118 again may be fit to a sphere having a radius equal to a gravitational constant, such as shown in FIG. 4. The recursive least squares estimation may be used to determine a center of the sphere by subtracting a first data sample of the plurality of data samples taken at a first time from a second data sample of the plurality of data samples taken at a second time, wherein the center corresponds to the bias.

As noted, accelerometer samples at different time instants may be used simultaneously. If [aₓ_{₀} a_{y}_{₀} a_{z}_{₀}] represents an accelerometer measurement at time t₀ the Cartesian coordinate relationship expressed by Equation 25 above may be written as Equation 32 and if [aₓ_{₁} a_{y}_{₁} a_{z}_{₁}] represents another accelerometer measurement at time t₁, Equation 25 may be rewritten as Equation 33.

aₓ_{₀}¹−2aₓ_{₀}bₓ_{₀}+bₓ_{₀}²+a_{y}_{₀}²−2a_{y}_{₀}b_{y}_{₀}+b_{y}_{₀}²a_{z}_{₀}²−2a_{z}_{₀}b_{z}_{₀}+b_{z}_{₀}²=r² (32)

aₓ_{₁}²−2aₓ_{₁}bₓ_{₁}+bₓ_{₁}²+a_{y}_{₁}²−2a_{y}_{₁}b_{y}_{₁}+b_{y}_{₁}²a_{z}_{₁}²−2a_{z}_{₁}b_{z}_{₁}+b_{z}_{₁}²=r² (33)

Correspondingly, by subtracting Equation 32 from Equation 33, the r² cancels out and results in Equation 34, that may be seen to take the general form of Equation 2, thereby allowing the recursive least squares estimation represented by Equations 4-6 to be performed to solve for the bias.

$$( {a}_{{x}_{1}} - {a}_{{x}_{0}} ) 2 ( {a}_{{y}_{1}} - {a}_{{y}_{0}} ) 2 ( {a}_{{z}_{1}} - {a}_{{z}_{0}} ) ] [ \begin{matrix}{b}_{x} \\ {b}_{y} \\ {b}_{z}\end{matrix} ] = ( {a}_{{x}_{1}}^{2} - {a}_{{x}_{0}}^{2} ) + ( {a}_{{y}_{1}}^{2} - {a}_{{y}_{0}}^{2} ) + ( {a}_{{z}_{1}}^{2} - {a}_{{z}_{0}}^{2} ) \qquad ( 34 )$$

According to one aspect of the disclosure, calibration module 122 may further be configured to filter the influence of kinematic forces that may exist during the movement of device 100. As will be described, statistical metrics may be employed to determine whether data from accelerometer 118 is suitable for inclusion into the recursive least squares estimation operation and/or whether a derived bias may be applied to subsequent data output by the accelerometer. For example, a data sample may be included in the recursive least squares estimation based at least in part on a comparison of the data sample to the standard deviation determined from a plurality of samples. Further, a derived bias may be used based at least in part on the covariance value and innovation value determined during the recursive least squares estimation.

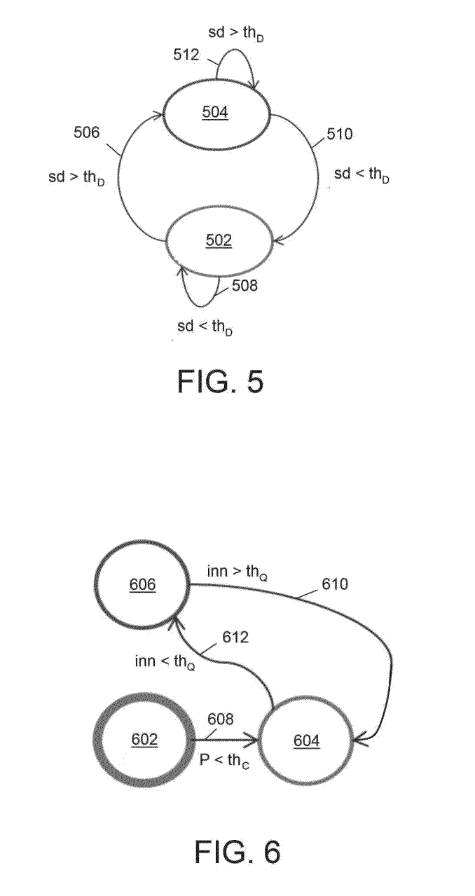

In an embodiment, calibration module 124 may employ a state machine to determine whether a given data sample is used during the recursive least squares estimation. As shown in FIG. 5, state 502 may represent that device 100 is experiencing relatively calm conditions, such that data from accelerometer 118 may be suitable for performing the recursive least squares estimation calibration. Correspondingly, state 504 may indicate that sufficient kinematics were detected and the data may not be suitable for calibration, resulting in the current data being discarded. The standard deviation of the raw data obtained from accelerometer 118 may be determined with respect to each orthogonal axis in order to generate sd, a 3-vector. Transitions between state 502 and 504 may be based at least in part on comparison of sd to a suitable disturbance threshold, th_{D}. As an example, the disturbance threshold may be 0.01 g, such that the threshold is exceeded if any component of the vector sd exceeds 0.01 g. However, any suitable threshold may be employed depending upon the desired operating characteristics and anticipated conditions to be experience by device 100. Accordingly, trigger 506 may cause a transition from state 502 to state 504 when sd>th_{D} and trigger 508 may result in no change from state 502 when sd<th_{D}. Likewise, trigger 510 may cause a transition from state 504 to state 502 when sd<th_{D}. and trigger 512 may result in no change from state 504 when sd>th_{D} as shown.

Further, after a data sample is included in the recursive least squares estimation and a bias for accelerometer 118 is derived, calibration module 124 may employ another state machine to determine whether to apply the derived bias to subsequent output from accelerometer 118. As shown in FIG. 6, state 602 may represent that insufficient data samples have been processed. In turn, state 604 may represent relatively calm conditions for device 100, such that the currently derived bias may be applied to data being output from accelerometer 118, while state 606 may indicate that sufficient disturbance exists so that the currently derived bias may not be trusted and a previously derived bias should be applied. Triggers causing transitions between these states may be based at least in part on a comparison of the maximum diagonal covariance value, P, of the recursive least squares estimation to a convergence threshold, th_{C} and on a comparison of the innovation value, inn, of the recursive least squares estimation to a quality threshold, th_{Q}. The innovation value may be calculated in the form of (Y−H*x)², where Y and H are data matrices and x is the bias estimate. In one aspect, th_{C} may be 0.1 μT² and th_{Q} may be 3 mg, but it should be appreciated that other suitable thresholds may be employed as desired.

As shown, the state machine may be initiated in state 602 and trigger 608 may transition to state 604 when P<th_{C}. If inn<th_{Q}, the bias estimate may be determined to have been derived under sufficiently calm conditions and correspondingly may be used to calibrate accelerometer 118. Accordingly, trigger 610 may cause a transition from state 604 to state 606 when inn>th_{Q}, causing the current bias estimate to be discarded and reverting to a previously derived bias estimate and covariance value P. Similarly, trigger 612 may cause a transition from state 606 to state 604 when inn<th_{Q}.

In further embodiments, calibration module 122 may be configured to perform a recursive least squares estimation to determine bias in magnetometer 120. As will be appreciated, the magnitude of the Earth's magnetic field may be relatively constant for a plurality of samples output by magnetometer 120. As such, the techniques described above with regard to accelerometer 118 may be adapted for use in deriving bias in a hard-iron calibration for magnetometer 120 by replacing the accelerometer output a(t) with the magnetometer output m(t) and determining a reference vector corresponding to the Earth's magnetic field rather than the gravity vector in the above discussions and equations.

Furthermore, the innovation vector, c−a^{t}x from Equation 4 may be employed as an indicator showing whether a disturbance or anomaly in the environmental magnetic field exists. In normal condition, the innovation sequence may represent white noise. Accordingly, if the whiteness property is no longer valid, it may be taken as signaling a magnetic anomaly. As desired, if a magnetic anomaly is detected, calibration module 122 may suspend the recursive least squares estimation process with regard to magnetometer 120 and sensor fusion module 124 may discard magnetometer data, relying on gyroscope 116 and accelerometer 118 to determine orientation information. As desired, sensor fusion module 124 may be configured to resume using magnetometer data when the innovation vector indicates the magnetic anomaly has dissipated or when the confidence of the gyroscope bias estimate is not sufficiently high, for example due to bias instability or temperature drift. In some implementations, magnetometer 120 may experience a bias shift due to magnetization from a strong anomaly. As such, calibration module 122 may be configured to reset the covariance matrix P to large values and restart the recursive least squares estimation calibration when the magnetic anomaly is removed.

As desired, calibration module 122 may further be configured to filter the influence of magnetic anomalies or disturbances that may corrupt data being subjected to the recursive least squares estimation. Notably, the output of magnetometer 120 may include the sensed environmental magnetic field and the sensor bias. While in normal conditions, the sensed environmental magnetic field is close to constant in world coordinate frame (e.g. equal to the Earth's magnetic field outdoors) and may not be affected by motion of device 100. Correspondingly, magnetometer calibration may not require a motionless state associated with accelerometer calibration. However, consumer-grade magnetometers may exhibit a poor signal-to-noise ratio and it may be desirable for the recursive least squares estimation to utilize data samples when device 100 undergoes an orientation change that is significantly larger than noise perturbation.

Accordingly, statistical metrics may be employed to determine whether data from magnetometer 120 is suitable for inclusion into the recursive least squares estimation operation and/or whether a derived bias may be applied to subsequent data output by the magnetometer. For example, a data sample may be included in the recursive least squares estimation based at least in part on a comparison of the data sample to the standard deviation determined from a plurality of samples and an absolute value of the difference between a first data sample and the derived bias. Further, a derived bias may be used based at least in part on determining an absolute value of a difference between a reference radius and a distance with respect to the derived bias and the first data sample and a maximum diagonal covariance value.

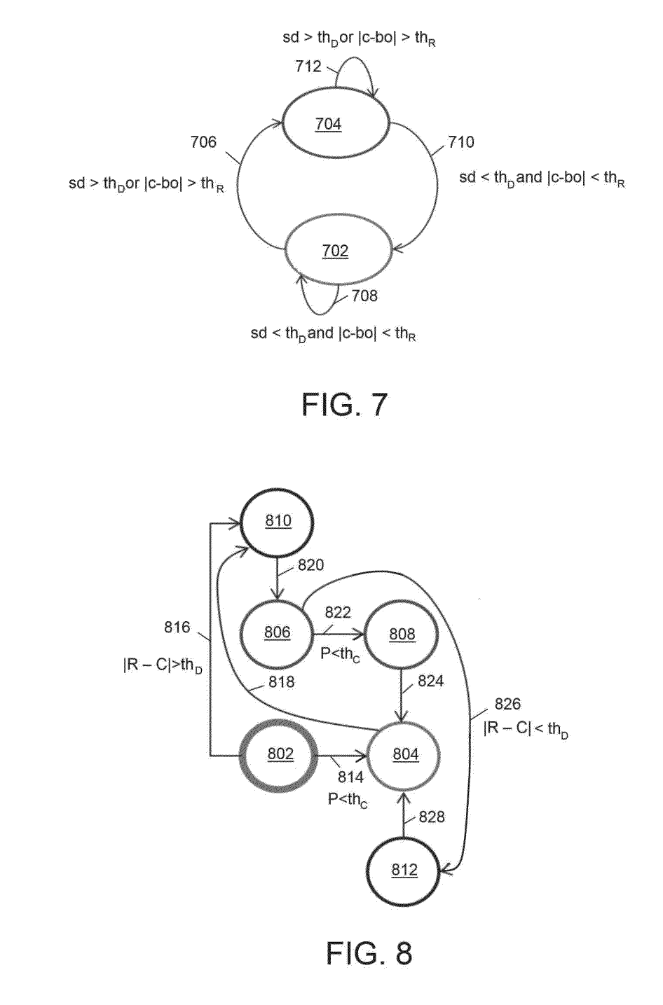

In an embodiment, calibration module 124 may employ a state machine to determine whether a given data sample is used during the recursive least squares estimation during magnetometer calibration. As shown in FIG. 7, state 702 may represent that device 100 is experiencing relatively normal magnetic conditions, such that data from magnetometer 120 may be suitable for performing the recursive least squares estimation calibration. Correspondingly, state 704 may indicate that sufficient anomalies or other disturbances were detected and the data may not be suitable for calibration, resulting in the current data being discarded. The standard deviation of the raw data obtained from magnetometer may be determined with respect to each orthogonal axis in order to generate sd, a 3-vector. Transitions between state 702 and 704 may be based at least in part on comparison of sd to a suitable disturbance threshold, th_{D}. As an example, the disturbance threshold may be 15 μT, such that the threshold is exceeded if any component of the vector sd exceeds 15 μT. Further, the absolute value of the difference between raw magnetometer data, c, and bias_offset vector, bo, which may be used to shift the magnetometer data to a more suitable numeric range may be expressed as a 3-vector |c−bo| and compared to a range threshold th_{R}. As an example, the range threshold may be 200 μT, such that the threshold is exceeded if any component of the vector |c−bo| exceeds 200 μT. As previously noted, any suitable threshold may be employed depending upon the desired operating characteristics and anticipated conditions to be experience by device 100.

Accordingly, trigger 706 may cause a transition from state 702 to state 704 when sd>th_{D} or |c−bo|>th_{R} while trigger 708 may result in no change from state 702 when sd<th_{D} and |c−bo|<th_{R}. Likewise, trigger 710 may cause a transition from state 704 to state 702 when sd<th_{D} and |c−bo|<th_{R} while trigger 712 may result in no change from state 704 when sd>th_{D} or |c−bo|>th_{R} as shown.

Further, after a data sample is included in the recursive least squares estimation and a bias for magnetometer 120 is derived, calibration module 124 may employ another state machine to determine whether to apply the derived bias to subsequent output from magnetometer 120. As shown in FIG. 8, state 802 may represent that insufficient data samples have been processed. In turn, state 804 may represent a lack of significant magnetic disturbances are being experienced by device 100, such that the currently derived bias estimate may be applied to data being output from magnetometer 120. Next, state 806 and state 808 may both represent that sufficient magnetic disturbances exist so that the currently derived bias may not be trusted, resulting in calibration module 122 undertaking the different actions described below depending upon whether the recursive least squares estimation has converged or not. Finally, state 810 and state 812 may represent transition states having the consequences specified below depending on the entry conditions.

Triggers causing transitions between the noted states may be based at least in part on a comparison of the maximum diagonal covariance value, P, of the recursive least squares estimation to a convergence threshold, th_{C}. The triggers may also be based on a comparison of the an absolute value of a difference between a reference radius, R, and a current Euclidian distance, C, from an accepted previous bias, xa, and the current magnetometer sample, c, expressed as |R−C|, to a difference threshold, th_{D} In one aspect, th_{C} may be 0.05 μT² and th_{D} may be 6 μT, but it should be appreciated that other suitable thresholds may be employed as desired. The state machine may also be implemented using a disturbance flag, d, having a value of 1 when sufficient magnetic disturbances are currently detected and a value of 0 when not.

As shown, the state machine may be initiated in state 802 and trigger 814 may transition to state 804 when P<th_{C} such that d=0 and convergence indicates that a bias estimate derived in state 804 may be accepted and used to calibrate magnetometer 120. However, trigger 816 transitions to state 810 if |R−C|>th_{D}, which indicates that a significant magnetic disturbance has been detected. Similarly, trigger 818 transitions from state 804 to state 810 if |R−C|>th_{D}. Then, in state 810 the disturbance flag may be set to 1 and the recursive least squares estimation may be reset by establishing a baseline bias, such as zero, and setting P to its large initial value. Upon reset, trigger 820 transitions from state 810 to state 806. The disturbance flag remains set at 1 and calibration module 122 may determine whether the detected magnetic disturbance remains relatively constant. If it is constant, the covariance matrix P will converge and when P<th_{C}, trigger 822 may transition from state 806 to 808. Since this transition indicates that convergence has occurred, the bias derived from the recursive least squares estimation may be accepted and likewise, it may be determined that the disturbance is stable, causing d to be set to 0 and trigger 824 may transition to state 804 for operation as described above. However, if the magnetic disturbance is not constant, P may not converge and the process may remain in state 806. Alternatively, if the detected disturbance dissipates, trigger 824 transitions from state 806 to state 812 when |R−C|<th_{D}. Since state 812 indicates that the magnetic disturbance has been removed, d may be set to 0 and a previously derived bias estimate and covariance matrix may be employed. State 812 then transitions to state 804 as indicated by trigger 826.

In a further aspect, some MEMS designs may result in superior bias behavior on certain axes (e.g. X and Y axes) than others (e.g. Z axis). The recursive least square calibration algorithm may be simplified to calibrate only the inferior axis. Typically, the recursive least squares estimation may involve executing Equations 4-6 for each axis. If desired to update only the bias for one axis, to increase computational or power efficiency for example, during iterations for the other axes, Equations 5 and 6 may be executed, but Equation 4 may be skipped while all the equations may be executed for iterations involving the inferior axis.

In another aspect, bias values and scale factors for MEMS sensors may be affected by chip temperature changes. By employing a temperature sensor as external sensor 108, it will be appreciated that a temperature dependency curve for bias or scale factor may be determined by recording the temperature sensor data whenever a new estimate is generated by the corresponding recursive least squares estimation calibration. Correspondingly, a standard curve fitting technique using the recursive least squares estimation represented by Equations 4-6 may be employed to determine the temperature dependence and provide an appropriate compensation.

Still further, the covariance matrix P determined from Equations 4-6 may be employed as a confidence metric indicating the calibration status. As noted, the diagonal elements of P may be set to a large initial value at the start of the recursive least squares estimation. As the recursive least squares estimation converges, the P diagonal elements will approach very small values, representing increasing confidence. Similarly, when disturbance or interference occurs, the P value may be large indicating decreased confidence. As desired, sensor fusion module 124 may employ the P values when determining whether to apply the current bias estimation in the sensor fusion operation.

Although the present invention has been described in accordance with the embodiments shown, one of ordinary skill in the art will readily recognize that there could be variations to the embodiments and those variations would be within the spirit and scope of the present invention. Accordingly, many modifications may be made by one of ordinary skill in the art without departing from the spirit and scope of the present invention.

What is claimed is:

1. A method for calibrating a motion sensor comprising:
obtaining a plurality of data samples from the motion sensor;
performing a recursive least squares estimation to update a mean and a covariance matrix for each of the plurality of data samples; and
deriving a bias estimate for the motion sensor from the mean and covariance matrix.

2. The method of claim 1, wherein the motion sensor is a gyroscope.

3. The method of claim 2, wherein each of the plurality of data samples comprises a measured angular rate, further comprising:
obtaining a corrected attitude for each sample from sensor fusion data;
determining an angular rate corresponding to the corrected attitude; and
performing the recursive least squares estimation using each measured angular rate and each determined angular rate to derive the bias.

4. The method of claim 1, wherein the motion sensor is an accelerometer.

5. The method of claim 1, further comprising determining a standard deviation using the plurality of data samples and performing the least square estimation for a first data sample depending on a comparison to the standard deviation.

6. The method of claim 5, further comprising determining a covariance value and an innovation value with respect to the first data sample and deriving the bias using the first data sample depending on a comparison to the covariance value and the innovation value.

7. The method of claim 4, further comprising:
rotating each of the plurality of data samples to a world coordinate frame;
determining a gravity vector for each of the rotated plurality of data samples;
setting the determined gravity vectors equal; and
performing the recursive least squares estimation to derive the bias.

8. The method of claim 4, further comprising:
fitting the plurality of data samples to a sphere having a radius equal to a gravitational constant; and
performing the recursive least squares estimation to determine a center of the sphere by computing Cartesian coordinates of the plurality of data samples, wherein the center corresponds to the bias.

9. The method of claim 8, wherein computing Cartesian coordinates of the plurality of data samples comprises grouping non-linear terms as an unknown in the recursive least squares estimation.

10. The method of claim 4, further comprising:
fitting the plurality of data samples to a sphere having a radius equal to a gravitational constant;
generating a first vector from a pair of data samples of the plurality of data samples,
generating a second vector from another pair of data samples of the plurality of data samples; and
performing the recursive least squares estimation to determine a center of the sphere by computing an intersection of perpendiculars of the first vector and the second vector, wherein the center corresponds to the bias.

11. The method of claim 4, further comprising:
fitting the plurality of data samples to a sphere having a radius equal to a gravitational constant; and
performing the recursive least squares estimation to determine a center of the sphere by subtracting a first data sample of the plurality of data samples taken at a first time from a second data sample of the plurality of data samples taken at a second time, wherein the center corresponds to the bias.

12. The method of claim 1, wherein the motion sensor is a magnetometer.

13. The method of claim 12, further comprising determining an innovation vector corresponding to the recursive least squares estimation and detecting a magnetic anomaly based at least in part on the innovation vector.

14. The method of claim 12, further comprising:
determining a standard deviation using the plurality of data samples;
determining an absolute value of the difference between a first data sample and the derived bias; and
performing the recursive least square estimate with respect to the first data sample depending on a comparison to the standard deviation and the absolute value.

15. The method of claim 14, further comprising:
determining an absolute value of a difference between a reference radius and a distance with respect to the derived bias and the first data sample;
determining a maximum diagonal covariance value with respect to the first sample; and
deriving the bias using the first data sample depending on a comparison to the absolute value and the maximum diagonal covariance value.

16. The method of claim 12, further comprising:
rotating each of the plurality of data samples to a world coordinate frame;
determining a reference vector corresponding to the Earth's magnetic field for each of the rotated plurality of data samples;
setting the determined reference vectors equal; and
performing the recursive least squares estimation to derive the bias.

17. The method of claim 12, further comprising:
fitting the plurality of data samples to a sphere having a radius equal to a magnitude of the Earth's magnetic field;
performing the recursive least squares estimation to determine a center of the sphere by computing Cartesian coordinates of the plurality of data samples, wherein the center corresponds to the bias.

18. The method of claim 17, wherein computing Cartesian coordinates of the plurality of data samples comprises grouping non-linear terms as an unknown in the recursive least squares estimation.

19. The method of claim 12, further comprising:
fitting the plurality of data samples to a sphere having a radius equal to a magnitude of the Earth's magnetic field;
generating a first vector from a pair of data samples of the plurality of data samples,
generating a second vector from another pair of data samples of the plurality of data samples;
performing the recursive least squares estimation to determine a center of the sphere by computing an intersection of perpendiculars of the first vector and the second vector, wherein the center corresponds to the bias.

20. The method of claim 14, further comprising:
fitting the plurality of data samples to a sphere having a radius equal to a magnitude of the Earth's magnetic field;
performing the recursive least squares estimation to determine a center of the sphere by subtracting a first data sample of the plurality of data samples taken at a first time from a second data sample of the plurality of data samples taken at a second time, wherein the center corresponds to the bias.

21. The method of claim 1, wherein the sensor is calibrated on a single axis.

22. The method of claim 1, further comprising sensing a temperature of the motion sensor and providing a temperature compensation to the calibration based at least in part on the sensed temperature.

23. The method of claim 22, wherein the temperature compensation is determined using a recursive least squares estimation.

24. The method of claim 1, further comprising determining a confidence metric based at least in part on the covariance matrix.

25. A sensor device comprising;
at least one motion sensor outputting a plurality of data samples; and
a calibration module configured to perform a recursive least squares estimation to update a mean and a covariance matrix for each of the plurality of data samples and derive a bias estimate for the motion sensor from the mean and covariance matrix.

26. The sensor device of claim 25, wherein the motion sensor is a gyroscope.

27. The sensor device of claim 26, wherein each of the plurality of data samples comprises a measured angular rate and wherein the calibration module is configured to:
obtain a corrected attitude for each sample from sensor fusion data;
determine an angular rate corresponding to the corrected attitude; and
perform the recursive least squares estimation using each measured angular rate and each determined angular rate to derive the bias.

28. The sensor device of claim 25, wherein the motion sensor is an accelerometer.

29. The sensor device of claim 25, wherein the calibration module is configured to determine a standard deviation using the plurality of data samples and perform the least square estimation for a first data sample depending on a comparison to the standard deviation.

30. The sensor device of claim 29, wherein the calibration module is configured to determine a covariance value and an innovation value with respect to the first data sample and derive the bias using the first data sample depending on a comparison to the covariance value and the innovation value.

31. The sensor device of claim 28, wherein the calibration module is configured to:
rotate each of the plurality of data samples to a world coordinate frame;
determine a gravity vector for each of the rotated plurality of data samples;
set the determined gravity vectors equal; and
perform the recursive least squares estimation to derive the bias.

32. The sensor device of claim 28, wherein the calibration module is configured to:
fit the plurality of data samples to a sphere having a radius equal to a gravitational constant; and
perform the recursive least squares estimation to determine a center of the sphere by computing Cartesian coordinates of the plurality of data samples, wherein the center corresponds to the bias.

33. The sensor device of claim 32, wherein computing Cartesian coordinates of the plurality of data samples comprises grouping non-linear terms as an unknown in the recursive least squares estimation.

34. The sensor device of claim 28, wherein the calibration module is configured to:
fit the plurality of data samples to a sphere having a radius equal to a gravitational constant;
generate a first vector from a pair of data samples of the plurality of data samples,
generate a second vector from another pair of data samples of the plurality of data samples;
perform the recursive least squares estimation to determine a center of the sphere by computing an intersection of perpendiculars of the first vector and the second vector, wherein the center corresponds to the bias.

35. The sensor device of claim 28, wherein the calibration module is configured to:
fit the plurality of data samples to a sphere having a radius equal to a gravitational constant; and
perform the recursive least squares estimation to determine a center of the sphere by subtracting a first data sample of the plurality of data samples taken at a first time from a second data sample of the plurality of data samples taken at a second time, wherein the center corresponds to the bias.

36. The sensor device of claim 25, wherein the motion sensor is a magnetometer.

37. The sensor device of claim 36, wherein the calibration module is configured to determine an innovation vector corresponding to the recursive least squares estimation and detect a magnetic anomaly based at least in part on the innovation vector.

38. The sensor device of claim 36, wherein the calibration module is configured to:
determine a standard deviation using the plurality of data samples;
determine an absolute value of the difference between a first data sample and the derived bias; and
perform the recursive least square estimate with respect to the first data sample depending on a comparison to the standard deviation and the absolute value.

39. The sensor device of claim 38, wherein the calibration module is configured to:
determine an absolute value of a difference between a reference radius and a distance with respect to the derived bias and the first data sample;
determine a maximum diagonal covariance value with respect to the first sample; and
derive the bias using the first data sample depending on a comparison to the absolute value and the maximum diagonal covariance value.

40. The sensor device of claim 36, wherein the calibration module is configured to:
rotate each of the plurality of data samples to a world coordinate frame;
determine a reference vector corresponding to the Earth's magnetic field for each of the rotated plurality of data samples;
set the determined reference vectors equal; and
perform the recursive least squares estimation to derive the bias.

41. The sensor device of claim 36, wherein the calibration module is configured to:
fit the plurality of data samples to a sphere having a radius equal to a magnitude of the Earth's magnetic field; and
perform the recursive least squares estimation to determine a center of the sphere by computing Cartesian coordinates of the plurality of data samples, wherein the center corresponds to the bias.

42. The sensor device of claim 41, wherein computing Cartesian coordinates of the plurality of data samples comprises grouping non-linear terms as an unknown in the recursive least squares estimation.

43. The sensor device of claim 36, wherein the calibration module is configured to:
fit the plurality of data samples to a sphere having a radius equal to a magnitude of the Earth's magnetic field;
generate a first vector from a pair of data samples of the plurality of data samples,
generate a second vector from another pair of data samples of the plurality of data samples; and
perform the recursive least squares estimation to determine a center of the sphere by computing an intersection of perpendiculars of the first vector and the second vector, wherein the center corresponds to the bias.

43. The sensor device of claim 36, wherein the calibration module is configured to:
fit the plurality of data samples to a sphere having a radius equal to a magnitude of the Earth's magnetic field; and
perform the recursive least squares estimation to determine a center of the sphere by subtracting a first data sample of the plurality of data samples taken at a first time from a second data sample of the plurality of data samples taken at a second time, wherein the center corresponds to the bias.

44. The sensor device of claim 25, wherein the sensor is calibrated on a single axis.

45. The sensor device of claim 25, further comprising a temperature sensor, wherein the calibration module is configured to provide temperature compensation to the calibration based at least in part on the sensed temperature.

46. The sensor device of claim 45, wherein the calibration module is configured to determine the temperature compensation using a recursive least squares estimation.

47. The sensor device of claim 25, wherein the calibration module is configured to determine a confidence metric based at least in part on the covariance matrix.

48. A self-calibrating sensor device comprising at least one motion sensor outputting a plurality of data samples and a calibration module configured to derive a bias estimate for the motion sensor, wherein the at least one motion sensor and the calibration module are implemented on a single substrate.
